(19) United States
(12) Patent Application Publication
(10) Pub. No.: US 2013/0221469 A1
(43) Pub. Date: Aug. 29, 2013

(54) SEMICONDUCTOR PACKAGE AND METHOD OF FABRICATING THE SAME

(71) Applicant: Dongbu HiTek Co., Ltd., (US)

(72) Inventor: Sunghyok KIM, Seoul (KR)

(73) Assignee: Dongbu HiTek Co., Ltd., Seoul (KR)

(21) Appl. No.: 13/734,154

(22) Filed: Jan. 4, 2013

(30) Foreign Application Priority Data
Feb. 29, 2012 (KR) 10-2012-0021131

(51) Int. Cl. H01L 31/0203; H01L 21/768; H01L 23/498

(52) U.S. Cl. CPC H01L 31/0203; H01L 23/49816; H01L 21/768
USPC 257/433; 257/738; 438/667

(57) ABSTRACT

A semiconductor package including a semiconductor chip configured to include a connection terminal electrically connected to wirings for transferring signals. The semiconductor package may include a semiconductor supporting substrate configured to be bonded to the semiconductor chip and include a through-silicon via which allows the connection terminal to be opened. The connection terminal may be formed on a scribe line of a semiconductor wafer and a conductive material contacting the connection terminal may filled in the through-silicon via.

The present application claims priority to Korean Patent Application No. 10-2012-0021131 (filed on Feb. 29, 2012), which is hereby incorporated by reference in its entirety.

### BACKGROUND

A CMOS image sensor is a device which may convert optical images into electrical signals using CMOS technology. In comparison a CCD image sensor with a CMOS image sensor with a CCD image sensor, the CMOS image sensor may have advantages. For example, a CMOS image sensor has a relatively simple driving scheme and can implement various scanning schemes. As another example, a CMOS image sensor may be miniaturized to minimize product size by integrating signal processing circuits on a single chip, but may also save fabrication costs by using a compatible CMOS technology. As yet another example, a CMOS image sensor may have relatively low power consumption.

With the development image sensor technology, the size of photodiodes has been reduced to increase the number of pixels on a chip without increasing the size of the chip. For example, the light receiving area of an image sensor is reduced. Additionally, in a front-side illumination structure, light loss may be caused due to several layers (e.g., metal layers) formed over the light receiving areas, which may result in deterioration of the sensitivity of the photodiode.

Backside illumination (BSI) image sensors may be capable of removing interference phenomenon of light from metal layers formed over the light receiving area. The back side illumination scheme forms a first substrate over which photodiodes are disposed, forms a second substrate (e.g. as a support substrate) under the first substrate and then, and bonds the first substrate and the second substrate to each other by compression. For example, a bonding technology for implementing the BSI may be classified into an oxide-to-oxide process or a metal-to-metal process. A packaging technology using a “Through-silicon via” (TSV) scheme has been implemented.

However, the packaging technology using BSI image sensors in accordance with the related art is relatively complicate in the wiring process for electrical connection to a top metal pad after the through silicon via process.

### SUMMARY

Embodiments relate to a semiconductor package fabricating technology in which two chips can use same connection terminal and same conductive material that are formed by a through-silicon via on a wafer scribe line and divided by wafer scribing(or dicing) process.

In accordance with embodiments, a semiconductor package may include at least one of: (1) A semiconductor chip including a connection terminal electrically connected to wirings for transferring signals; and (2) A semiconductor supporting substrate bonded to the semiconductor chip and including a through-silicon via opening the connection terminal. In embodiments, the connection terminal is formed on a scribe line of a semiconductor wafer and a conductive material contacting the connection terminal is filled in the through-silicon via.

In embodiments, the conductive material may be diced along the scribe line. The semiconductor package may be bonded to a printed circuit board and may be electrically connected to the printed circuit board through the conductive material, in accordance with embodiments. The conductive material may be filled in from a solder ball type material. In embodiments, the conductive material may include a metal material filled by an electroplate mechanism. In embodiments, the metal material may include copper (Cu). In embodiments, the semiconductor chip may include an image sensor chip.

Embodiments relate to a method of forming a semiconductor package, including least one of: (1) Opening a connection terminal included in a semiconductor chip by forming a through-silicon via on a semiconductor support substrate bonded to the semiconductor chip; and (2) dicing a conductive material along a semiconductor scribe line after filling the conductive material in the through-silicon via. In embodiments, the connection terminal may be formed on the semiconductor scribe line.

In embodiments, a method may include electrically connecting the connection terminal to the printed circuit board through the conductive material by bonding the semiconductor support board to the printed circuit board. In embodiments, the filling of the conductive material in the through-silicon via includes filling a metal material of a solder ball type. In embodiments, said filling the conductive material in through-silicon via includes filling a metal material by an electroplate mechanism. In embodiments, the semiconductor chip may include an image sensor chip.

In accordance with embodiment, when the connection terminal in the semiconductor chip (e.g. the image sensor chip) is electrically connected to the printed circuit board (PCB), the connection terminal opened through the through-silicon via may be formed on the wafer scribe line, the conductive material of the solder ball type may be filled in the through-silicon via through which the connection terminal is opened, and the connection terminal and the conductive material may be finally diced along the scribe line to use two wafer chips by being divided into the same two connection terminals and two conductive materials. Accordingly, it may be possible (in accordance with embodiments) to remove the processes of electrically connecting the connection terminal to the printed circuit board (e.g. extending a connection line between the connection terminal and PCB or similar arrangements).

### DRAWINGS

The objects and features of embodiments will become apparent from the following description of embodiments given in conjunction with the accompanying drawings, in which:

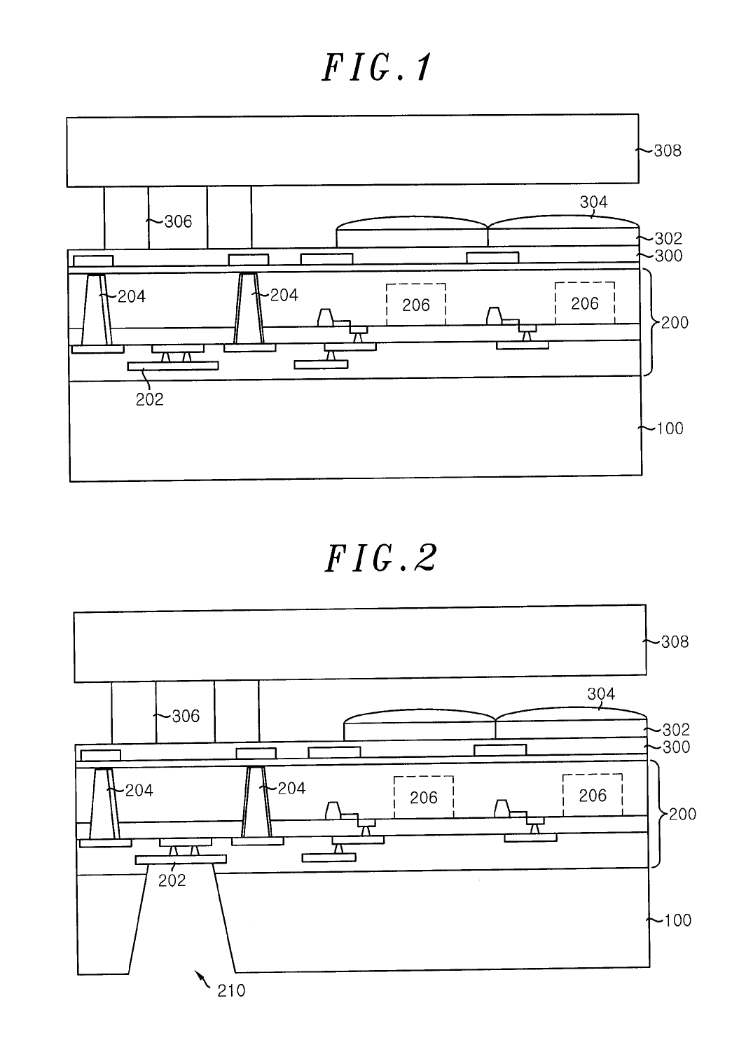

Example FIG. 1 is a cross sectional view of a back side illumination (BSI) CMOS image sensor which is used in a method for fabricating a semiconductor package, in accordance with embodiment.

Example FIG. 2 is a cross sectional view of a process in which a connection terminal is opened by forming a through-silicon via for the BSI CMOS image sensor shown in FIG. 1, in accordance with embodiments.

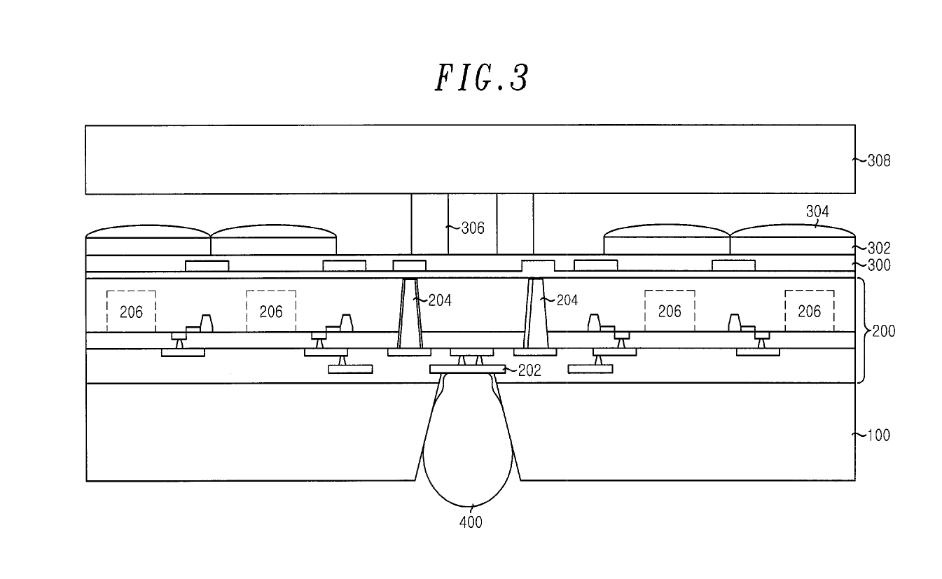

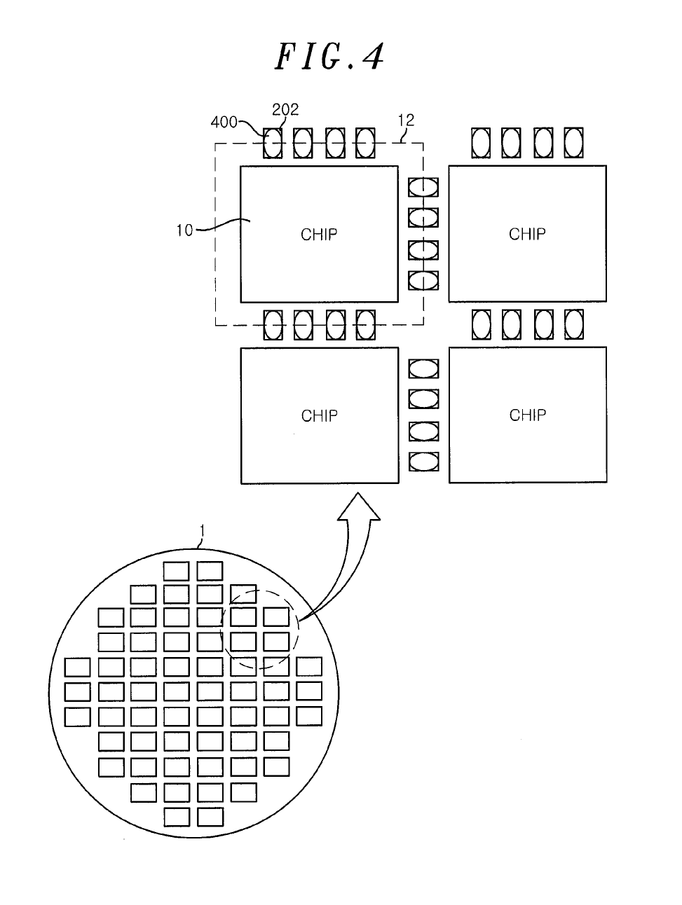

Example FIG. 3 is a cross sectional view of a process in which a conductive material (e.g. a solder ball) is filled in the through-silicon via shown in FIG. 2, in accordance with embodiments.

Example FIG. 4 is a plane view of a wafer and a chip after the process of FIG. 3, in accordance with embodiments.

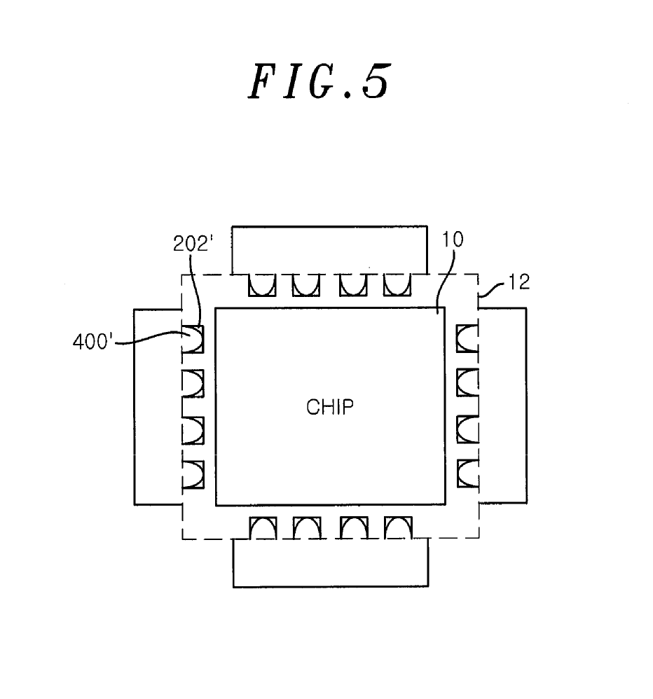

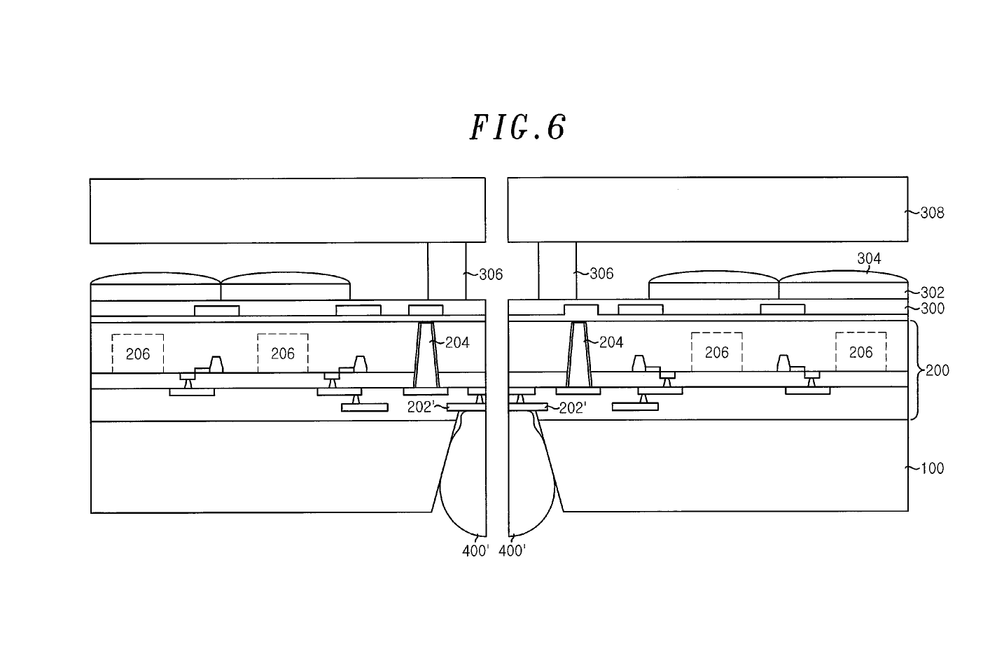

Example FIG. 5 is a plane view illustrating the connection terminal and the solder ball diced along the scribe line shown in FIG. 4, in accordance with embodiments.

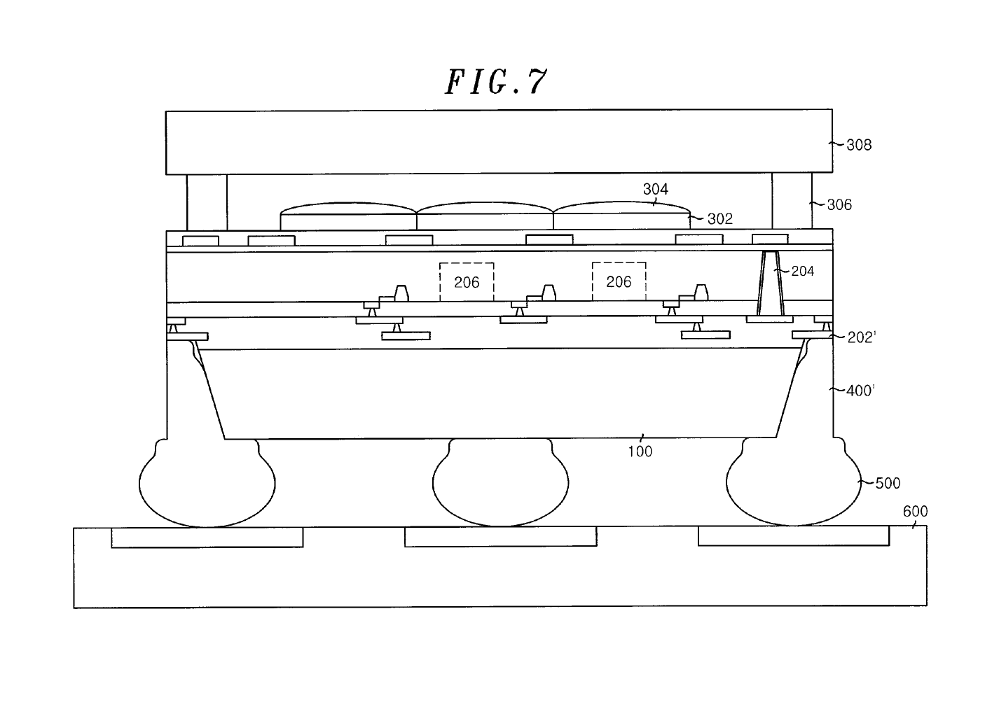

Example FIG. 6 is a cross sectional view of a process in which the connection terminal and the solder ball are diced along the scribe line shown in FIG. 4, in accordance with embodiments.

Example FIG. 7 is a cross sectional view illustrating a process in which the connection terminal is electrically connected to the printed circuit board (PCB) through the solder ball by bonding the semiconductor package fabricated via the processes of FIGS. 1 to 6 to the PCB, in accordance with embodiments.

### DESCRIPTION

Embodiments will be described herein, including the best mode known to the inventors for carrying out the invention. Variations of those embodiments may become apparent to those of ordinary skill in the art upon reading the foregoing description. The inventors expect skilled artisans to employ such variations as appropriate, and the inventors intend for the embodiments to be practiced other than as specifically described herein. Accordingly, embodiments include all modifications and equivalents of the subject matter recited in the claims appended hereto as permitted by applicable law. Moreover, any combination of the above-described elements in all possible variations thereof is encompassed by the embodiments.

In the following description of the embodiments, if the detailed description of the already known structure and operation may confuse the subject matter of the embodiments, the detailed description thereof may be omitted. In embodiments, functions described in the blocks or the sequences may run out of order. For example, two successive blocks and sequences may be substantially executed simultaneously or often in reverse order according to corresponding functions.

Embodiments may be fabricated by forming the connection terminal opened through a through-silicon via on a wafer scribe line. In embodiments, a connection terminal in an image sensor chip may be electrically connected to a printed circuit board (PCB). In embodiments, a conductive material of a solder ball type may be filled in the through-silicon via through which the connection terminal is opened. In embodiments, the connection terminal may be diced and the conductive material along the scribe line may use at least two wafer chips that are divided into the same connection terminal and conductive material.

Example FIG. 1 is a cross sectional view of a back side illumination (BSI) CMOS image sensor (CIS) which is used in a method for fabricating a semiconductor package, in accordance with embodiments. A BSI CMOS image sensor may include at least one of a semiconductor support substrate 100, a semiconductor chip 200, a connection terminal 202, device isolation layer 204, photodetectors 206, a planarized layer 300, color filters 302, micro lenses 304, adhesive layers 306, and/or a glass substrate 308. Example semiconductor chip 200, which may be a donor wafer including an image sensor (or similarly configured device), may include an epitaxial wafer (e.g. epi Wafer), a silicon on insulator, and/or similar structure.

A plurality of wirings may be included in the semiconductor chip 200, which may be formed by the same scheme as a fabricating scheme of front-side illumination image sensor. The connection terminal 202 may be electrically connected with wirings for transferring pixel signals through photodetectors 206 and may correspond to a top metal layer of the semiconductor chip 200. The photodetector 206 may be a photodiode and may receive specific optical signals through the micro lenses 304, the color filters 302, and/or similarly configured devices. The semiconductor support substrate 100 may include a carrier wafer and may be formed of an epitaxial layer (or similar configurations).

FIG. 1 is a cross sectional view of BSI CMOS image sensor in accordance with embodiments. Semiconductor support substrate 100 may be bonded on the semiconductor chip 200, which may be flipped. At least one of planarized layer 300, color filters 302, and/or micro lenses 304 may be sequentially formed thereon. Glass substrate 308 may be boned thereon through the adhesive layers 306.

In embodiments, semiconductor chip 200 may be subjected to an etch-back process to a predetermined thickness (e.g. ranging from 0.5 μm to 4 μm). The color filters 302 and the micro lenses 304 may be disposed in consideration of a path of the optical signals incident to the photodetectors 206. A grinding process may be performed on the semiconductor support substrate 100. Semiconductor support substrate 100 may be formed at a predetermined thickness (e.g., ranging from 50 μm to 300 μm) by the grinding process.

Example FIG. 2 is a cross sectional view of a process in which a connection terminal is opened by forming a through-silicon via 210 for the BSI CMOS image sensor, in accordance with embodiments. Through-silicon via 210 may be formed by a through silicon via (TSV) process (or similar process). The connection terminal 202 may be opened by partially etching the semiconductor support substrate 100 by a through silicon via process. In order to open the connection terminal 202, an etch-back process, a photomask process, or the like, may be implemented after depositing insulating materials such as oxide, nitride, or similar material.

Example FIG. 3 is a cross sectional view of a process in which a conductive material (e.g. solder ball 400) is filled in the through-silicon via shown in FIG. 2, in accordance with embodiments. In forming the solder ball 400, the size of the through-silicon via 210 (which allows the connection terminal 202 to be opened) is formed to have a relatively large size so that the solder ball 400 can be thickly formed to be swollen up to a top surface of the semiconductor support substrate 100. In embodiments, the size of the through-silicon via 210 may range from 50 μm to several millimeters. In order to form the solder ball 400, various mechanisms may be used and therefore the embodiments are not limited to a specific mechanism.

In embodiments, solder ball 400 may be used as the conductive material, although this is just one example embodiments. In embodiments, various types of metal materials may be used as a substitute for solder ball 400. For example, instead of the solder ball 400, metal materials (e.g. copper (Cu)) may be filled by an electroplate mechanism, in accordance with embodiments.

Example FIG. 4 is a plane view of a wafer 1 and a chip 10 after the process illustrated FIG. 3 (or similar process), in accordance with embodiments. The opened connection terminal 202 and the conductive material 400 connected to the connection terminal 202 may be formed on a scribe line 12 of the wafer 1.

Example FIG. 5 is a plane view of the connection terminal 202 and the solder ball 400 diced along the scribe line 12 shown in FIG. 4. Example FIG. 6 is a cross sectional view of a process in which the connection terminal 202 and the solder ball 400 are diced along the scribe line 12 shown in FIG. 4, in accordance with embodiments.

As shown in example FIGS. 5 and 6, the connection terminal 202 and the conductive material 400 may be formed on the scribe line 12 of the wafer 1 and the connection terminal 202 and the conductive material 400 shown in FIG. 4 may be diced along the scribe line 12 such that each of two chips may use the diced connection terminal 202′ and filled conductive material 400′, respectively. Reference numeral 202′ may represent a connection terminal after the dicing process and reference numeral 400′ may represent a conductive material after the dicing process.

Example FIG. 7 is a cross sectional view of a process in which the connection terminal 202′ is electrically connected to a printed circuit board (PCB) 600 through a solder ball 400′ by bonding the semiconductor package fabricated via the processes of FIGS. 1 to 6 to the PCB 600, in accordance with embodiments. In order to electrically connect the connection terminal 202′ to the PCB 600, an additional conductive material (e.g., a solder ball 500) may be formed. The solder ball 500 may be formed as a bump (or similar structure), in accordance with embodiments. As a result, the connection terminal 202′ that may be diced along the scribe line 12 may be electrically connected with the PCB 600 through the conductive material 400′ and the solder ball 500.

In accordance with embodiments, when the connection terminal in the semiconductor chip (e.g., the image sensor chip) is electrically connected to the PCB, the connection terminal opened through the through-silicon via may be formed on the wafer scribe line. In embodiments, the conductive material (e.g., the solder ball) may be filled in the through-silicon via through which the connection terminal is opened. In embodiments, the connection terminal and the conductive material can be diced along the scribe line such that each of two chips uses the diced connection terminal and conductive material, respectively.

While embodiments has been shown and described, the embodiments are not limited thereto. It will be understood by those skilled in the art that various changes and modifications may be made without departing from the scope of the embodiments as defined in the following claims.

What is claimed is:

1. An apparatus comprising:
a semiconductor chip comprising a connection terminal electrically connected to wirings that are configured to transfer signals; and
a semiconductor supporting substrate bonded to the semiconductor chip;
a through-silicon via in the semiconductor supporting substrate configured to open the connection terminal, wherein the connection terminal is formed on a scribe line of a semiconductor wafer and a conductive material is filled in the through-silicon via to contact the connection terminal.

2. The apparatus of claim 1, wherein the apparatus is a semiconductor package.

3. The apparatus of claim 1, wherein the conductive material is diced along the scribe line.

4. The apparatus of claim 1, wherein the semiconductor package is bonded to a printed circuit board (PCB) and is electrically connected to the PCB through the conductive material.

5. The apparatus of claim 1, wherein the conductive material comprises a solder ball.

6. The apparatus of claim 1, wherein the conductive material includes a metal material filled by an electroplating mechanism.

7. The apparatus of claim 6, wherein the metal material comprises copper (Cu).

8. The apparatus of claim 1, wherein the semiconductor chip comprises an image sensor chip.

9. A method of fabricating a semiconductor package, comprising:
opening a connection terminal comprised in a semiconductor chip by forming a through-silicon via through a semiconductor support substrate bonded to the semiconductor chip; and
dicing a conductive material along a semiconductor scribe line after filling the conductive material in the through-silicon via, wherein the connection terminal is formed on the semiconductor scribe line.

10. The method of claim 9, comprising electrically connecting the connection terminal to the printed circuit board (PCB) through the conductive material by bonding the semiconductor support board to the PCB.

11. The method of claim 9, wherein:
said filling the conductive material in the through-silicon via includes filling metal solder ball material in the through-silicon via.

12. The method of claim 9, wherein said filling the conductive material in the through-silicon via includes filling metal material using an electroplating process.

13. The method of claim 9, wherein the semiconductor chip comprises an image sensor chip.
